(19) United States
(12) Patent Application Publication
(10) Pub. No.: US 2017/0005242 A1
(43) Pub. Date: Jan. 5, 2017

(54) SEMICONDUCTOR LIGHT EMITTING DEVICE

(71) Applicant: SAMSUNG ELECTRONICS CO., LTD., Suwon-si (KR)

(72) Inventors: Myeong Ha KIM, Hwaseong-si (KR); Sang Yeob SONG, Suwon-si (KR); Chan Mook LIM, Yongin-si (KR)

(73) Assignee: SAMSUNG ELECTRONICS CO., LTD., Suwon-si (KR)

(21) Appl. No.: 15/138,326

(22) Filed: Apr. 26, 2016

(30) Foreign Application Priority Data
Jul. 3, 2015 (KR) 10-2015-0095120

(51) Int. Cl. H01L 33/50; H01L 33/32; H01L 33/46; H01L 33/06

(52) U.S. Cl. CPC H01L 33/508; H01L 33/06; H01L 33/32; H01L 33/46

(57) ABSTRACT

A semiconductor light emitting device may include a substrate having a first surface and a second surface, the second surface being opposite to the first surface; a light emitting structure disposed on the first surface of the substrate and including a first conductivity-type semiconductor layer, an active layer and a second conductivity-type semiconductor layer; and a reflector disposed on the second surface of the substrate and including a low refractive index layer and a Bragg layer, wherein the Bragg layer includes a plurality of alternately stacked layers having different refractive indices, and wherein a refractive index of the low refractive index layer is lower than a refractive index of the Bragg layer.

### CROSS-REFERENCE TO RELATED APPLICATION

This application claims priority from Korean Patent Application No. 10-2015-0095120, filed on Jul. 3, 2015, with the Korean Intellectual Property Office, the disclosure of which is incorporated herein in its entirety by reference.

### BACKGROUND

1. Field

Apparatuses consistent with example embodiments relate to a semiconductor light emitting device.

2. Description of the Related Art

Semiconductor light emitting devices emit light through the recombination of electrons and holes when power is applied thereto, and are commonly used as light sources due to various characteristics such as low power consumption, high levels of luminance, compactness, and the like. In particular, utilization of nitride-based semiconductor light emitting devices has been greatly expanded and the nitride-based semiconductor light emitting devices are commonly employed as light sources in backlight units of display devices, general lighting devices, headlights of vehicles, and the like.

As semiconductor light emitting devices are widely used, the semiconductor light emitting devices are utilized in the field of high current, high output light sources. Accordingly, research has been conducted to improve light emitting efficiency in the field of high current and high output light sources. In particular, a semiconductor light emitting device including a reflector and a method for manufacturing the same have been proposed in order to improve external light extraction efficiency.

### SUMMARY

One or more example embodiments may provide a semiconductor light emitting device having improved light extraction efficiency.

According to an aspect of an example embodiment, a semiconductor light emitting device may include: a substrate having a first surface and a second surface, the second surface being opposite to the first surface, a light emitting structure disposed on the first surface of the substrate and including a first conductivity-type semiconductor layer, an active layer and a second conductivity-type semiconductor layer, and a reflector disposed on the second surface of the substrate and including a low refractive index layer and a Bragg layer, wherein the Bragg layer may include a plurality of alternately stacked layers having different refractive indices, and a refractive index of the low refractive index layer may be lower than a refractive index of the Bragg layer.

The low refractive index layer may include a plurality of layers.

The low refractive index layer may include a first refractive layer and a second refractive index layer, and the first and second refractive index layers may be disposed on first and second surfaces of the Bragg layer, respectively.

The first low refractive index layer, the Bragg layer, and the second low refractive index layer may be sequentially stacked on the substrate.

The first and second refractive index layers may have different thicknesses.

The first and second refractive index layers may have the same refractive index or different refractive indices.

The light reflected by the first refractive index layer has a wavelength different from a wavelength of light reflected by the second refractive index layer.

The low refractive index layer may have a refractive index (n), which is in a range of 1≦n<1.4.

The low refractive index layer may have a thickness of 0.8λ/n or greater, where λ denotes a wavelength of light generated by the active layer and n denotes a refractive index of the low refractive index layer.

The low refractive index layer may include at least one selected from the group consisting of porous SiO₂, porous SiO and MgF₂.

The low refractive index layer may be disposed on a surface of the Bragg layer.

The Bragg layer may include first layers having a first refractive index and second layers having a second refractive index higher than the first refractive index, and the refractive index of the low refractive index layer may be lower than the first refractive index of the first layers.

At least one of the low refractive index layer and the Bragg layer may include a dielectric material.

According to an aspect of another example embodiment, a semiconductor light emitting device may include: a light emitting structure including a first conductivity-type semiconductor layer, an active layer and a second conductivity-type semiconductor layer, a Bragg layer disposed on a surface of the light emitting structure and including plurality of alternately stacked layers having different refractive indices, and a low refractive index layer disposed on at least one surface of the Bragg layer and having a refractive index lower than a refractive index of the Bragg layer.

The Bragg layer may include first layers having a first refractive index and second layers having a second refractive index higher than the first refractive index, and the low refractive index layer may have a thickness greater than a thickness of each of the first and second layers.

According to an aspect of still another example embodiment, A semiconductor light emitting diode (LED) chip may include a first surface, on which a first electrode and a second electrode are disposed, and a second surface being opposite to the first surface, the semiconductor LED chip further including a reflector disposed on the second surface of the semiconductor LED chip, wherein the reflector includes a low refractive index layer and a Bragg layer, a refractive index of the low refractive index layer being lower than a refractive index of the Bragg layer.

The low refractive index layer may have a refractive index (n), which is in a range of 1≦n<1.4.

The low refractive index layer may have a thickness equal to or greater than about 300 nm.

The low refractive index layer may be provided to at least one surface of the Bragg layer.

The low refractive index layer may include a plurality of refractive index layers having the same refractive index or different refractive indices.

### BRIEF DESCRIPTION OF DRAWINGS

The above and/or other aspects will be more apparent by describing certain example embodiments with reference to the accompanying drawings in which:

FIG. 1 is a schematic cross-sectional view of a semiconductor light emitting device according to an example embodiment;

FIG. 2 is a graph illustrating characteristics of a semiconductor light emitting device according to an example embodiment;

FIG. 3 is a schematic cross-sectional view of a semiconductor light emitting device according to another example embodiment;

FIG. 4 is a schematic cross-sectional view of a semiconductor light emitting device according to another example embodiment;

FIG. 5 is a schematic cross-sectional view of a modified example of a semiconductor light emitting device according to an example embodiment;

FIG. 6 illustrates an example of a package to which a semiconductor light emitting device according to an example embodiment is applied;

FIGS. 7A and 7B are schematic views of a white light source module employing the semiconductor light emitting device package illustrated in FIG. 6;

FIG. 8 is a CIE 1931 chromaticity diagram illustrating properties of a wavelength conversion material usable in the semiconductor light emitting device package illustrated in FIG. 6;

FIG. 9 is a perspective view of a backlight unit including a semiconductor light emitting device according to an example embodiment;

FIG. 10 is a cross-sectional view of a backlight unit including a semiconductor light emitting device according to an example embodiment;

FIG. 11 is an exploded perspective view schematically illustrating a lamp including a communication module as an example of a lighting device including a semiconductor light emitting device according to an example embodiment;

FIG. 12 is an exploded perspective view schematically illustrating a bar-type lamp as an example of a lighting device including a semiconductor light emitting device according to an example embodiment;

FIG. 13 schematically illustrates an indoor lighting control network system employing a semiconductor light emitting device according to an example embodiment;

FIG. 14 schematically illustrates an example of an open-type network system employing a semiconductor light emitting device according to an example embodiment; and

FIG. 15 is a block diagram illustrating communications between a mobile device and a smart engine of a lighting fixture employing a semiconductor light emitting device according to an example embodiment through visible light communications.

### DETAILED DESCRIPTION

Various example embodiments will now be described more fully with reference to the accompanying drawings in which some example embodiments are shown. The disclosure may, however, be embodied in different forms and should not be construed as limited to the embodiments set forth herein. Rather, these embodiments are provided so that this disclosure is thorough and complete and fully conveys the disclosure to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the disclosure.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

An example embodiment can be implemented differently, and functions or operations described in a particular block may occur in a different way from a flow described in the flowchart. For example, two consecutive blocks may be performed simultaneously, or the blocks may be performed in reverse according to related functions or operations.

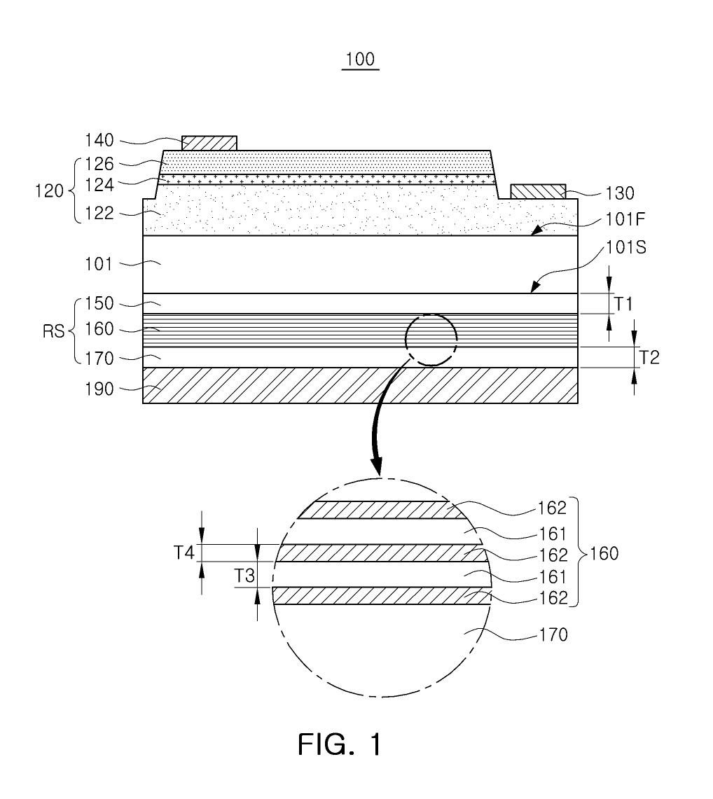

FIG. 1 is a schematic cross-sectional view of a semiconductor light emitting device according to an example embodiment.

Referring to FIG. 1, a semiconductor light emitting device 100 includes a substrate 101 having first and second surfaces 101F and 101S, a light emitting structure 120 disposed on the first surface 101F of the substrate 101, and a reflector RS disposed on the second surface 101S of the substrate 101. The light emitting structure 120 includes a first conductivity-type semiconductor layer 122, an active layer 124 and a second conductivity-type semiconductor layer 126, and the reflector RS includes first and second low refractive index layers 150 and 170 and a Bragg layer 160. In addition, the semiconductor light emitting device 100 further includes first and second electrodes 130 and 140 as an electrode structure and a metal layer 190 disposed below the reflector RS. The substrate 101 and the light emitting structure 120 may provide a semiconductor light emitting diode (LED) chip.

The substrate 101 may be provided as a substrate for semiconductor growth. The substrate 101 may include an insulating, conductive or semiconductor material, such as sapphire, SiC, MgAl₂O₄, MgO, LiAlO₂, LiGaO₂, or GaN. In a case of the substrate 101 including sapphire, a crystal having Hexa-Rhombo R3C symmetry, the sapphire substrate has a lattice constant of 13.001 Å on a C-axis and a lattice constant of 4.758 Å on an A-axis and includes a C (0001) plane, an A (11-20) plane, an R (1-102) plane, and the like. The C plane is mainly used as a substrate for nitride semiconductor growth because the C plane facilitates growth of a nitride film and is stable at high temperatures. In particular, in the present embodiment, the substrate 101 may be a light transmissive substrate.

Although not shown, a plurality of unevenness structures may be formed on the first surface 101F of the substrate 101, that is, a growth surface thereof on which the semiconductor layers are grown. Such unevenness structures may improve the crystallinity and light emitting efficiency of the semiconductor layers constituting the light emitting structure 120.

In example embodiments, a buffer layer may be further disposed on the substrate 101 to improve the crystallinity of the semiconductor layers constituting the light emitting structure 120. For example, the buffer layer may include AlₓGa₁₋ₓN which is grown at low temperature without doping.

In example embodiments, the substrate 101 may be omitted. In this case, the reflector RS may be disposed to contact the light emitting structure 120.

The light emitting structure 120 includes the first conductivity-type semiconductor layer 122, the active layer 124 and the second conductivity-type semiconductor layer 126. The first and second conductivity-type semiconductor layers 122 and 126 may include a semiconductor material doped with n-type and p-type impurities, respectively, but are not limited thereto. On the other hand, the first and second conductivity-type semiconductor layers 122 and 126 may include a semiconductor material doped with p-type and n-type impurities, respectively. For example, the first and second conductivity-type semiconductor layers 122 and 126 may include a nitride semiconductor such as a material having a composition of AlₓIn_{y}Ga_{1-x-y}N (0≦x≦1, 0≦y≦1, and 0≦x+y≦1). Each of the first and second conductivity-type semiconductor layers 122 and 126 may be formed as a single layer or may include a plurality of layers having different properties with respect to doping concentrations, compositions and the like. Alternatively, the first and second conductivity-type semiconductor layers 122 and 126 may include AlInGaP-based or AlinGaAs-based semiconductor. In the present example embodiment, for example, the first conductivity-type semiconductor layer 122 may include n-GaN doped with silicon (Si) or carbon (C), while the second conductivity-type semiconductor layer 126 may include p-GaN doped with magnesium (Mg) or zinc (Zn).

The active layer 124 may be disposed between the first and second conductivity-type semiconductor layers 122 and 126. The active layer 124 may emit light having a predetermined level of energy through electron-hole recombination. The active layer 124 may include a single material such as InGaN. Alternatively, the active layer 124 may have a single-quantum well (SQW) structure or a multi-quantum well (MQW) structure in which quantum well layers and quantum barrier layers are alternately stacked. For example, in a case of nitride semiconductor, a GaN/InGaN structure may be used. In a case in which the active layer 124 includes InGaN, an increase in the content of indium (In) may alleviate crystalline defects resulting from a lattice mismatch and improve internal quantum efficiency of the semiconductor light emitting device. In addition, wavelengths of light emitted from the active layer 124 may be adjusted according to the content of In within the active layer 124.

The first and second electrodes 130 and 140 may be disposed on the first and second conductivity-type semiconductor layers 122 and 126 to be electrically connected thereto, respectively. The first and second electrodes 130 and 140 may have a single-layer or multilayer structure formed of a conductive material. For example, the first and second electrodes 130 and 140 include at least one of gold (Au), silver (Ag), copper (Cu), zinc (Zn), aluminum (Al), indium (In), titanium (Ti), silicon (Si), germanium (Ge), tin (Sn), magnesium (Mg), tantalum (Ta), chrome (Cr), tungsten (W), ruthenium (Ru), rhodium (Rh), iridium (Jr), nickel (Ni), palladium (Pd), platinum (Pt) and alloys thereof. In example embodiments, at least one of the first and second electrodes 130 and 140 may be a transparent electrode. For example, the transparent electrode may include an indium tin oxide (ITO), an aluminum zinc oxide (AZO), an indium zinc oxide (IZO), a zinc oxide (ZnO), GZO(ZnO:Ga), an indium oxide (In₂O₃), a tin oxide (SnO₂), a cadmium oxide (CdO), a cadmium tin oxide (CdSnO₄), or a gallium oxide (Ga₂O₃).

The positions and shapes of the first and second electrodes 130 and 140 illustrated in FIG. 1 are merely example, and may be variously modified. In example embodiments, an ohmic electrode layer may be further disposed on the second conductivity-type semiconductor layer 126. For example, the ohmic electrode layer includes p-GaN containing high concentration p-type impurities. Alternatively, the ohmic electrode layer may include a metallic material or a transparent conductive oxide.

The reflector RS may be disposed on the second surface 1015 of the substrate 101 opposing the first surface 101F thereof on which the light emitting structure 120 is disposed, and includes the first and second low refractive index layers 150 and 170 and the Bragg layer 160. The reflector RS may have a reflective structure to redirect light having passed through the substrate 101, among light generated by the active layer 124, toward the upper portion of the light emitting structure 120. The reflector RS in the present embodiment may further improve light reflection efficiency through the first and second low refractive index layers 150 being disposed on both surfaces of the Bragg layer 160, respectively.

The Bragg layer 160 may be a distributed Bragg reflector (DBR). The Bragg layer 160 includes a plurality of layers having different refractive indices and alternately stacked. The Bragg layer 160 includes a first layer 161 having a low refractive index and a second layer 162 having a high refractive index. The first and second layers 161 and 162 may be alternately arranged at least once. The Bragg layer 160 may have a structure in which a single first layer 161 and a single second layer 162 are arranged or a structure in which two or more first layers 161 and two or more second layers 162 are alternately arranged.

The Bragg layer 160 may include a dielectric material. For example, the first layer 161 includes any one of SiO₂ (refractive index: approximately 1.46), Al₂O₃ (refractive index: approximately 1.68) and MgO (refractive index: approximately 1.7). For example, the second layer 162 includes any one of TiO₂ (refractive index: approximately 2.3), Ta₂O₅ (refractive index: approximately 1.8), ITO (refractive index: approximately 2.0), ZrO₂ (refractive index: approximately 2.05) and Si₃N₄ (refractive index: approximately 2.02).

When λ denotes a wavelength of light generated by the active layer 124 and n denotes a refractive index of the first or second layer 161 or 162, the first and second layers 161 and 162 may be formed to have a thickness of 0.2λ/n to 0.6λ/n. For example, the first and second layers 161 and 162 may be formed to have a thickness of λ/4n, but are not limited thereto. In the present embodiment, the first and second layers 161 and 162 may be formed to have a predetermined thickness within the Bragg layer 160. A thickness T3 of the first layer 161 may be greater than a thickness T4 of the second layer 162, but the thicknesses of the first and second layers 161 and 162 are not limited thereto.

The first and second low refractive index layers 150 and 170 may be disposed to contact both surfaces of the Bragg layer 160, respectively, and may serve to improve the reflectivity of the Bragg layer 160. However, this is only an example and the example embodiments are not limited thereto. For example, only one of the first and second low refractive index layers 150 and 170 may be disposed on the Bragg layer 160.

The first and second low refractive index layers 150 and 170 include a dielectric material having a relatively low refractive index, such as a refractive index of 1 to 1.4 (1≦n<1.4). The refractive indices of the first and second low refractive index layers 150 and 170 may be lower than those of the first and second layers 161 and 162 of the Bragg layer 160. In particular, the first and second low refractive index layers 150 and 170 may have lower refractive indices than the first layer 161 having a relatively low refractive index in the Bragg layer 160.

For example, the first and second low refractive index layers 150 and 170 include at least one selected from the group consisting of porous SiO₂, porous SiO and MgF₂. Therefore, the first and second low refractive index layers 150 and 170 include a material having a composition which is the same as that of the Bragg layer 160 and having a porous structure.

When λ denotes a wavelength of light generated by the active layer 124 and n denotes a refractive index of the first or second low refractive index layer 150 or 170, the first and second low refractive index layers 150 and 170 may be formed to have a thickness of 0.8λ/n or greater. In a case in which thicknesses T1 and T2 of the first and second low refractive index layers 150 and 170 are less than the aforementioned range, the reflectivity may not be substantially improved. The thicknesses T1 and T2 of the first and second low refractive index layers 150 and 170 may be greater than the thicknesses T3 and T4 of the first and second layers 161 and 162 of the Bragg layer 160.

The first and second low refractive index layers 150 and 170 of the reflector RS may be designed to reflect light having the same wavelength area or different wavelength areas. In example embodiments, the first and second low refractive index layers 150 and 170 may have the same structure. For example, the first and second low refractive index layers 150 and 170 may include the same material and may have the same thickness. Alternatively, to allow the first and second low refractive index layers 150 and 170 to reflect light having different wavelength areas, the first and second low refractive index layers 150 and 170 may include materials having different refractive indices and the thicknesses thereof may be differently selected.

The reflector RS may be designed to have a high reflectivity of about 95% or above with respect to the wavelength of the light generated by the active layer 124 by selecting appropriate refractive indices and thicknesses of the first and second layers 161 and 162 and the first and second low refractive index layers 150 and 170. In addition, the number of repeatedly stacked first and second layers 161 and 162 may be determined to provide high reflectivity.

The metal layer 190 may be disposed below the reflector RS, and may be combined with the reflector RS to thereby further improve reflectivity. In addition, the metal layer 190 may serve to protect the reflector RS when the semiconductor light emitting device 100 is mounted on a package substrate or the like. The metal layer 190 includes aluminum (Al), silver (Ag), nickel (Ni), rhodium (Rh), palladium (Pd), iridium (Jr), ruthenium (Ru), magnesium (Mg), zinc (Zn), platinum (Pt), gold (Au) or an alloy thereof. In example embodiments, the metal layer 190 may be omitted.

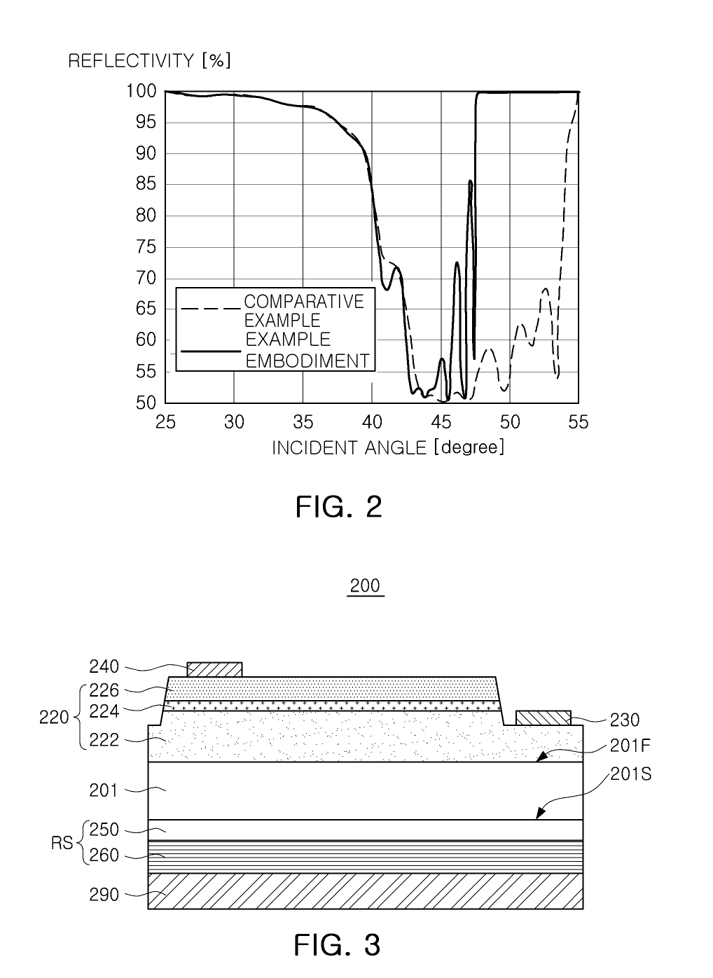

FIG. 2 is a graph illustrating the characteristics of a semiconductor light emitting device according to an example embodiment.

The graph shows results of simulation of reflectivity of a semiconductor light emitting device including a reflective layer having a single DBR structure according to a comparative example and the semiconductor light emitting device including the reflector RS as illustrated in FIG. 1 according to an example embodiment, depending on incident angles of light having a wavelength of 450 nm. In the simulation, the example embodiment is characterized as follows: the first layer 161 is formed of SiO₂ and the second layer 162 is formed of TiO₂; the first and second low refractive index layers 150 and 170 are formed of MgF₂ having a thickness of 300 nm; and the reflector RS includes a total of 39 layers.

Referring to FIG. 2, the reflectivity of the semiconductor light emitting device according to the comparative example was substantially reduced in an area having an incident angle of approximately 35 to 55 degrees. This area refers to an area in which the incident angle is equal to a Brewster angle and a peripheral area thereof. In this description, such an area in which reflectivity is reduced is referred to as a Brewster area. To alleviate the reduction of reflectivity in the Brewster area which occurs in the DBR structure, the number of alternately stacked low and high refractive index layers constituting the DBR structure may be increased. In general, in a case of a DBR structure including layers formed of SiO₂ and TiO₂, the Brewster angle is formed at 45.2 degrees, and the Brewster area corresponding thereto may have a substantial reduction of reflectivity.

According to example embodiments, the reflectivity in the Brewster area may be improved by forming the first and second low refractive index layers 150 and 170 on both surfaces of the Bragg layer 160 without increasing the number of alternately stacked low and high refractive index layers (see FIG. 1). In particular, in the present embodiment, it can be seen that reflectivity is improved when the incident angle is within the range of approximately 45 to 55 degrees. In addition, an area having improved reflectivity may be adjusted by controlling the thicknesses and number of the first and second low refractive index layers 150 and 170. This is because light incident at an angle corresponding to the Brewster angle is totally internally reflected by the low refractive index layers, thereby having improved reflectivity. In general, when light passes through two areas having different refractive indices, it is refracted at a predetermined angle. Light incident at an angle greater than or equal to a threshold angle of total internal reflection fails to pass through an upper area of the two areas and is totally internally reflected. The threshold angle of total internal reflection is determined depending on a difference in the refractive indices of the two areas at an interface thereof. In a case in which light is incident from an area having a refractive index of n1 to an area having a refractive index of n2, the threshold angle of total internal reflection is determined as arcsin(n2/n1). Therefore, as the refractive index of n2 is reduced, total internal reflection may easily occur. In the present embodiment, by disposing the low refractive index layer on one surface or both surfaces of the DBR, total internal reflection is facilitated. Therefore, even when light is incident to the DBR at an angle corresponding to the Brewster angle, it is totally internally reflected by the low refractive index layer, and thus, the Brewster area may be substantially reduced. As a result, the overall reflectivity of the reflector RS may be improved.

FIG. 3 is a schematic cross-sectional view of a semiconductor light emitting device according to another example embodiment. Repetitive descriptions to those described with reference to FIG. 1 will be omitted.

Referring to FIG. 3, a semiconductor light emitting device 200 includes a substrate 201 having first and second surfaces 201F and 201S, a light emitting structure 220 disposed on the first surface 201F of the substrate 201, and a reflector RS disposed on the second surface 201S of the substrate 201. The light emitting structure 220 includes a first conductivity-type semiconductor layer 222, an active layer 224 and a second conductivity-type semiconductor layer 226, and the reflector RS includes a low refractive index layer 250 and a Bragg layer 260. In addition, the semiconductor light emitting device 200 further includes first and second electrodes 230 and 240 as an electrode structure and a metal layer 290 disposed below the reflector RS. The present example embodiment differs from the previous example embodiment in that the low refractive index layer 250 is disposed only on one surface of the Bragg layer 260.

In the present example embodiment, the reflector RS includes the low refractive index layer 250 disposed on an upper surface of the Bragg layer 260, but is not limited thereto. Alternatively, the low refractive index layer 250 may be disposed only on a lower surface of the Bragg layer 260.

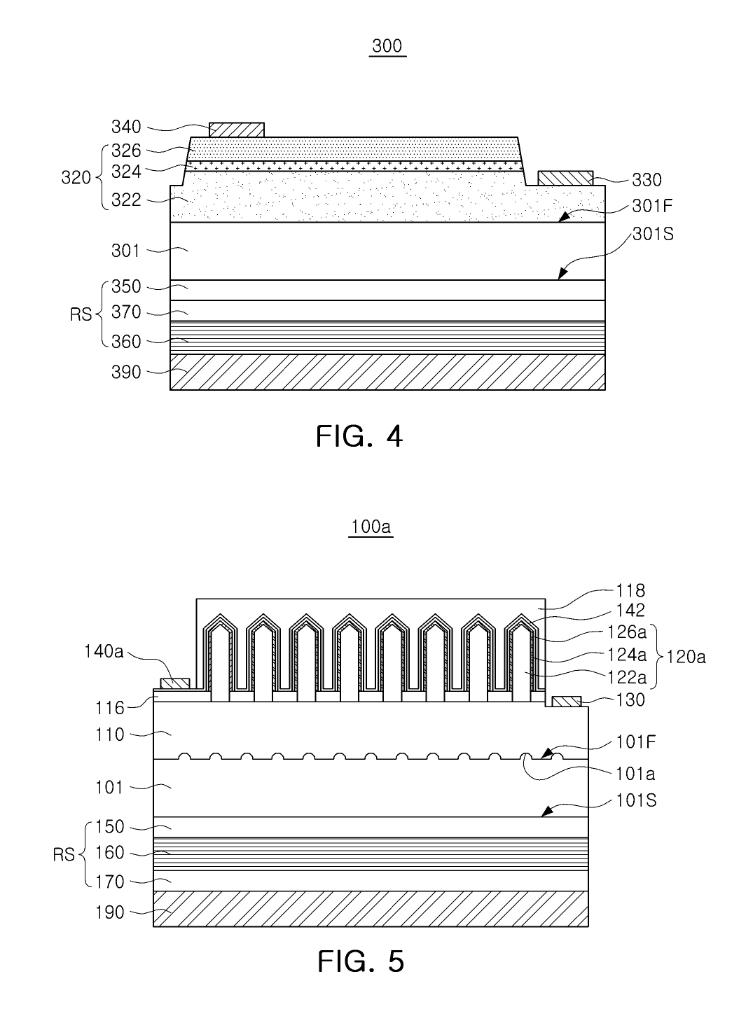

FIG. 4 is a schematic cross-sectional view of a semiconductor light emitting device according to another example embodiment. Repetitive descriptions to those described with reference to FIG. 1 will be omitted.

Referring to FIG. 4, a semiconductor light emitting device 300 includes a substrate 301 having first and second surfaces 301F and 301S, a light emitting structure 320 disposed on the first surface 301F of the substrate 301, and a reflector RS disposed on the second surface 301S of the substrate 301. The light emitting structure 320 includes a first conductivity-type semiconductor layer 322, an active layer 324 and a second conductivity-type semiconductor layer 326, and the reflector RS includes first and second low refractive index layers 350 and 370 and a Bragg layer 360. In addition, the semiconductor light emitting device 300 further includes first and second electrodes 330 and 340 as an electrode structure and a metal layer 390 disposed below the reflector RS. The present example embodiment differs from the previous example embodiments in that the first and second low refractive index layers 350 and 370 are disposed on one surface of the Bragg layer 360.

In the present example embodiment, the reflector RS includes the first and second low refractive index layers 350 and 370 disposed on an upper surface of the Bragg layer 360, but is not limited thereto. Alternatively, the first and second low refractive index layers 350 and 370 may be disposed on a lower surface of the Bragg layer 360.

FIG. 5 is a schematic cross-sectional view of a modified example of a semiconductor light emitting device according to an example embodiment. Repetitive descriptions to those described with reference to FIG. 1 will be omitted.

Referring to FIG. 5, a semiconductor light emitting device 100a includes a substrate 101 having first and second surfaces 101F and 101S, light emitting nanostructures 120a disposed on the first surface 101F of the substrate 101, and a reflector RS disposed on the second surface 101S of the substrate 101. The light emitting nanostructure 120a includes a first conductivity-type semiconductor core 122a, an active layer 124a and a second conductivity-type semiconductor layer 126a, and the reflector RS includes first and second low refractive index layers 150 and 170 and a Bragg layer 160. In addition, the semiconductor light emitting device 100a further includes a base layer 110 and an insulating layer 116 disposed between the substrate 101 and the light emitting nanostructures 120a, a transparent electrode layer 142 and a filler layer 118 covering the light emitting nanostructures 120a, first and second electrodes 130 and 140a as an electrode structure, and a metal layer 190 disposed below the reflector RS.

In the present example embodiment, a growth surface of the substrate 101 may be provided with unevenness structures 101a. The base layer 110 may be disposed on the first surface 101F of the substrate 101. The base layer 110 may include a Group III-V compound, such as GaN. For example, the base layer 110 may include n-GaN doped with n-type impurities. The base layer 110 may provide a crystal plane for growth of the first conductivity-type semiconductor core 122a, and may be connected to one ends of the light emitting nanostructures 120a to thereby serve as a contact electrode.

The insulating layer 116 may be disposed on the base layer 110. The insulating layer 116 may include a silicon oxide or a silicon nitride. For example, the insulating layer 116 may include at least one of SiOₓ, SiOₓN_{y}, SiₓN_{y}, Al₂O₃, TiN, AlN, ZrO, TiAlN, and TiSiN. The insulating layer 116 includes a plurality of openings exposing portions of the base layer 110. The diameters, lengths, positions and growth conditions of the light emitting nanostructures 120a may be determined according to sizes of the openings. The plurality of openings may have various shapes, such as a circular shape, a quadrangular shape or a hexagonal shape.

The plurality of light emitting nanostructures 120a may be positioned to correspond to the plurality of openings. Each light emitting nanostructure 120a may have a core-shell structure including the first conductivity-type semiconductor core 122a grown from the portion of the base layer 110 exposed through the opening, and the active layer 124a and the second conductivity-type semiconductor layer 126a sequentially formed on a surface of the first conductivity-type semiconductor core 122a.

The number of light emitting nanostructures 120a included in the semiconductor light emitting device 100a is not limited to that illustrated in FIG. 5. For example, the semiconductor light emitting device 100a includes tens of to hundreds of light emitting nanostructures 120a. The light emitting nanostructure 120a in the present example embodiment includes a hexagonal prismatic region in a lower portion thereof and a hexagonal pyramidal region in an upper portion thereof. According to example embodiments, the light emitting nanostructure 120a may have a pyramid shape or a columnar shape. Since the light emitting nanostructure 120a has a three-dimensional shape, a light emitting surface area thereof is relatively increased, and thus light emitting efficiency may be improved.

The transparent electrode layer 142 may cover the upper and side surfaces of the light emitting nanostructures 120a and may be extended between adjacent light emitting nanostructures 120a. For example, the transparent electrode layer 142 may include an indium tin oxide (no), an aluminum zinc oxide (AZO), an indium zinc oxide (IZO), a zinc oxide (ZnO), GZO (ZnO:Ga), an indium oxide (In₂O₃), a tin oxide (SnO₂), a cadmium oxide (CdO), a cadmium tin oxide (CdSnO₄), or a gallium oxide (Ga₂O₃).

The filler layer 118 may fill spaces between adjacent light emitting nanostructures 120a, and may be disposed to cover the light emitting nanostructures 120a and the transparent electrode layer 142 disposed on the light emitting nanostructures 120a. The filler layer 118 may include a light-transmissive insulating material. For example, the filler layer 118 includes a silicon oxide (SiO₂), a silicon nitride (SiNₓ), an aluminum oxide (Al₂O₃), a hafnium oxide (HfO), a titanium oxide (TiO₂), or a zirconium oxide (ZrO).

The first and second electrodes 130 and 140a may be disposed on the base layer 110 and the second conductivity-type semiconductor layer 124a to be electrically connected thereto, respectively.

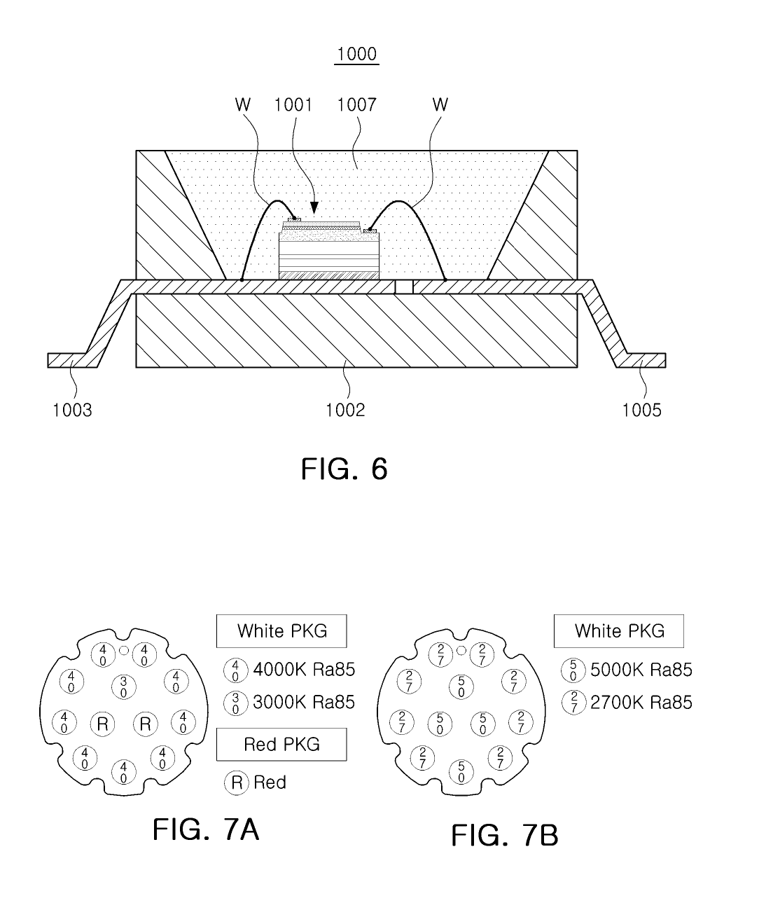

FIG. 6 illustrates an example of a package to which a semiconductor light emitting device according to an example embodiment is applied.

Referring to FIG. 6, a semiconductor light emitting device package 1000 includes a semiconductor light emitting device 1001, a package body 1002, and a pair of first and second lead frames 1003 and 1005. The semiconductor light emitting device 1001 may be mounted on the first and second lead frames 1003 and 1005 to be electrically connected to the first and second lead frames 1003 and 1005 through wires W. According to example embodiments, the semiconductor light emitting device 1001 may be mounted on a portion of the package 1000 other than the first and second lead frames 1003 and 1005 such as the package body 1002. In addition, the package body 1002 may have a cup-like shape to improve light reflective efficiency, and an encapsulant 1007 including a light transmissive material may be provided in the package body 1002 having the reflective cup shape to seal the semiconductor light emitting device 1001, the wires W, and the like.

In the present example embodiment, the semiconductor light emitting device package 1000 is illustrated as including the semiconductor light emitting device 1001 having a structure similar to that of the semiconductor light emitting device 100 illustrated in FIG. 1, but is not limited thereto. Alternatively, the semiconductor light emitting device package 1000 includes the modified semiconductor light emitting device 100a illustrated in FIG. 5.

FIGS. 7A and 7B are schematic views of a white light source module employing the semiconductor light emitting device package illustrated in FIG. 6.

Referring to FIGS. 7A and 7B, the light source module includes a plurality of semiconductor light emitting device packages mounted on a circuit board. The plurality of semiconductor light emitting device packages mounted in a single light source module may be homogeneous packages that generate light having substantially the same wavelength, or may be heterogeneous packages that generate light having different wavelengths as in the present example embodiment.

Referring to FIG. 7A, a while light source module may include a combination of white light emitting device packages having color temperatures of 4,000 K and 3,000 K and red light emitting device packages. The while light source module may provide white light having a color temperature which is adjustable in a range of 3,000 K to 4,000 K and having a color rendering index (CRI) Ra of 105 to 100.

Referring to FIG. 7B, a while light source module consists of white light emitting device packages, some of which provide white light having different color temperatures. For example, by combining white light emitting device packages having a color temperature of 2,700 K and white light emitting device packages having a color temperature of 5,000 K, the while light source module may provide white light having a color temperature which is adjustable in a range of 2,700 K to 5,000 K and having a color rendering index (CRI) Ra of 85 to 99. Here, the number of white light emitting device packages having a color temperature of 2,700 K or 5,000 K may differ according to a preset color temperature value of the light source module. For example, when the preset color temperature value of the white light source module is approximately 4,000 K, the number of white light emitting device packages having a color temperature of 4,000 K is more than the number of white light emitting device packages having a color temperature of 3,000 K or the number of red light emitting device packages.

In this manner, heterogeneous light emitting device packages include a light emitting device package emitting white light by combining a blue light emitting device with a yellow, green, red or orange phosphor and a light emitting device package including at least one of violet, blue, green, red and infrared light emitting devices, thereby adjusting the color temperature and color rendering index of white light.

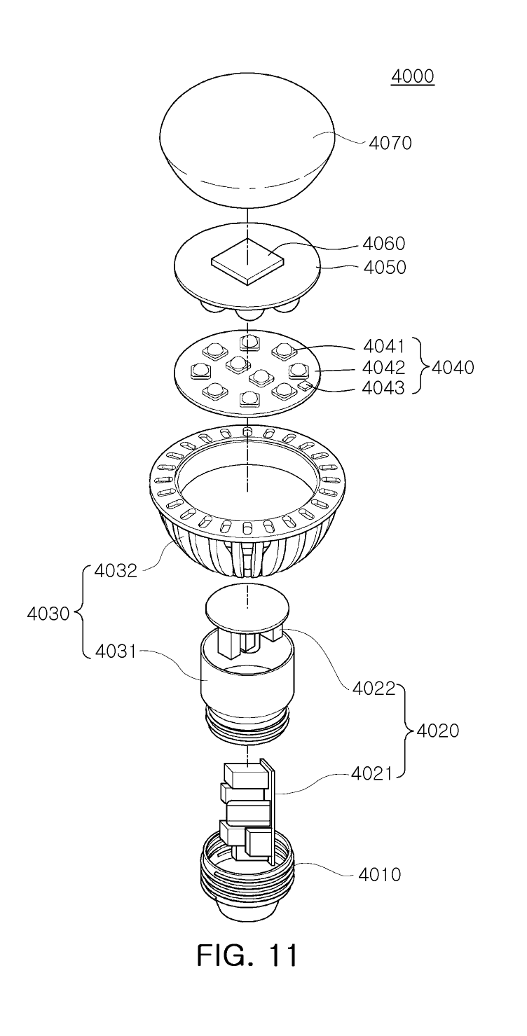

The aforementioned white light source module may be used as a light source module 4040 for a bulb-type lighting device 4000 (see FIG. 11).

In a single light emitting device package, light of a desired color may be determined according to wavelengths of light emitted by light emitting devices (e.g., LED chips) and types and mixing ratios of phosphors. In case of white light, color temperatures and color rendering indices may be adjusted.

For example, in a case in which a blue LED chip is combined with at least one of yellow, green, and red phosphors, a light emitting device package may emit white light having various color temperatures according to mixing ratios of phosphors. In addition, a light emitting device package in which a green or red phosphor is applied to a blue LED chip may emit green or red light. In this manner, the color temperature and color rendering index of white light may be adjusted by combining the light emitting device package emitting white light and the light emitting device package emitting green or red light. Here, the light emitting device package including at least one of violet, blue, green, red and infrared light emitting devices may also be used to form the white light source module.

In this case, the light source module may be controlled to generate white light of which a color rendering index (CRI) ranges from a CRI level of light emitted by a sodium lamp to a CRI level of sunlight and a color temperature ranges from 1,500 K to 20,000 K. Depending on an embodiment, by generating visible light having purple, blue, green, red, orange colors, or infrared light, an illumination color may be adjusted according to a surrounding atmosphere or mood. In addition, light having a special wavelength for stimulating plant growth may also be generated.

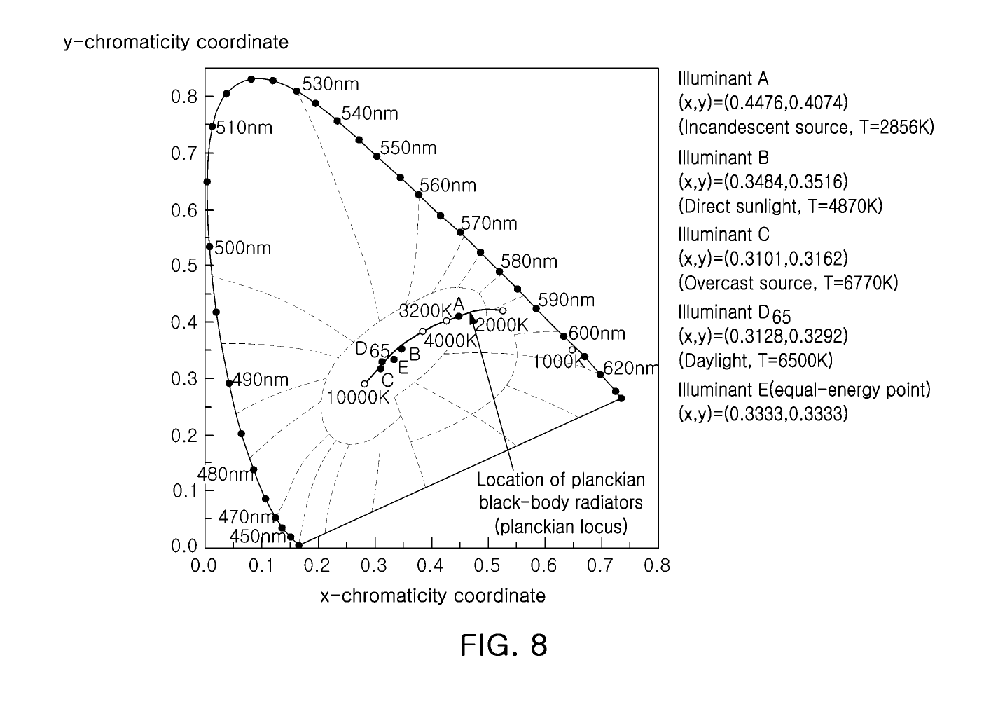

FIG. 8 is a CIE 1931 chromaticity diagram illustrating properties of a wavelength conversion material usable in the semiconductor light emitting device package illustrated in FIG. 6.

Referring to the CIE 1931 chromaticity diagram illustrated in FIG. 8, white light generated by combining a ultraviolet (UV) or blue LED with yellow, green, and red phosphors and/or green and red LEDs may have two or more peak wavelengths and may be positioned in a segment linking (x, y) coordinates (0.4476, 0.4074), (0.3484, 0.3516), (0.3101, 0.3162), (0.3128, 0.3292), (0.3333, 0.3333) of the CIE 1931 chromaticity diagram. Alternatively, white light may be positioned in a region surrounded by a spectrum of black body radiation and the segment. A color temperature of white light ranges from 2,000 K to 20,000 K. In FIG. 8, white light in the vicinity of a point E (0.3333, 0.3333) below the spectrum of black body radiation has a relatively reduced yellow light component, and thus, it may be considered to be bright and clean when sensed by the naked eye. Therefore, a lighting device using such white light may be effectively used in retail spaces for groceries, clothing, and the like.

To convert the wavelength of light emitted from a semiconductor light emitting device into a desired wavelength, various materials such as phosphors and/or quantum dots may be used.

Phosphors may have the following compositions and colors:

Oxide-based Phosphor: yellow and green Y₃Al₅O₁₂:Ce, Tb₃Al₅O₁₂:Ce, Lu₃Al₅O₁₂:Ce Silicate-based Phosphor: yellow and green (Ba,Sr)₂SiO₄:Eu, yellow and orange (Ba,Sr)₃SiO₅:Ce

Nitride-based Phosphor: green β-SiAlON:Eu, yellow La₃Si₆N₁₁:Ce, orange α-SiAlON:Eu, red CaAlSiN₃:Eu, Sr₂Si₅N₈:Eu, SrSiAl₄N₇:Eu, SrLiAl₃N₄:Eu, Ln₄₋ₓ(Eu_{z}M_{1-z})ₓSi_{12-y}Al_{y}O_{3+x+y}N_{18-x-y} (0.5≦x≦3, 0<z<0.3, 0<y≦4)—Formula (1) where, in formula (1), Ln is at least one element selected from the group consisting of Group Ma elements and rare earth elements, and M is at least one element selected from the group consisting of Ca, Ba, Sr and Mg.

Fluoride-based Phosphor: KSF-based red K₂SiF₆:Mn₄⁺, K₂TiF₆:Mn₄⁺, NaYF₄:Mn₄⁺, NaGdF₄:Mn₄⁺, K₃SiF₇:Mn⁴⁺

The compositions of the phosphors may comply with stoichiometry, and each element may be replaced with another element belonging to the same group in the periodic table. For example, strontium (Sr) may be replaced with barium (Ba), calcium (Ca), magnesium (Mg) or the like corresponding to alkaline earth metals (Group II elements), and yttrium (Y) may be replaced with terbium (Tb), Lutetium (Lu), scandium (Sc), gadolinium (Gd) or the like in the lanthanide group. In addition, an activator such as europium (Eu) or the like may be replaced with cerium (Ce), terbium (Tb), praseodymium (Pr), erbium (Er), ytterbium (Yb) or the like according to desired energy levels. The activator may be used alone, or a coactivator or the like for changes of properties may be additionally combined therewith.

In particular, to improve reliability under high temperature and high humidity, a fluoride-based red phosphor may be coated with a fluoride not containing Mn, or a surface thereof or a fluoride coated surface thereof may be coated with an organic material. Since the aforementioned fluoride-based red phosphor has a narrow full width at half maximum (FWHM) of 40 nm or less, the fluoride-based red phosphor may be used for high resolution televisions (TVs) such as ultra high definition (UHD) TVs.

Table 1 below shows types of phosphors that may be used in a white light emitting device using a blue LED chip (wavelength: 440 to 460 nm) or a UV LED chip (wavelength: 380 to 440 nm) according to application fields.

TABLE 1

| Purpose | Phosphors |
|---|---|
| LED TV Backlight Unit | β-SiAlON:Eu²⁺, (Ca,Sr)AlSiN₃:Eu²⁺, La₃Si₆N₁₁:Ce³⁺, |
| (BLU) | K₂SiF₆:Mn⁴⁺, SrLiAl₃N₄:Eu, Ln₄₋ₓ(Eu_{z}M_{1-z})ₓSi_{12-y}Al_{y}O_{3+x+y}N_{18-x-y} |
| | (0.5 ≦ x ≦ 3, 0 < z < 0.3, 0 < y ≦ 4), |
| | K₂TiF₆:Mn⁴⁺, NaYF₄:Mn⁴⁺, NaGdF₄:Mn⁴⁺, K₃SiF₇:Mn⁴⁺ |
| Lighting Devices | Lu₃Al₅O₁₂:Ce³⁺, Ca-α-SiAlON:Eu²⁺, La₃Si₆N₁₁:Ce³⁺, (Ca, |
| | Sr)AlSiN₃:Eu²⁺, Y₃Al₅O₁₂:Ce³⁺, K₂SiF₆:Mn⁴⁺, |
| | SrLiAl₃N₄:Eu, Ln₄₋ₓ(Eu_{z}M_{1-z})ₓSi_{12-y}Al_{y}O_{3+x+y}N_{18-x-y}(0.5 ≦ x ≦ |
| | 3, 0 < z < 0.3, 0 < y ≦ 4), K₂TiF₆:Mn⁴⁺, NaYF₄:Mn⁴⁺, |
| | NaGdF₄:Mn⁴⁺, K₃SiF₇:Mn⁴⁺ |
| Side Viewing | Lu₃Al₅O₁₂:Ce³⁺, Ca-α-SiAlON:Eu²⁺, La₃Si₆N₁₁:Ce³⁺, (Ca, |
| (Mobile, Notebook PC) | Sr)AlSiN₃:Eu²⁺, Y₃Al₅O₁₂:Ce³⁺, (Sr,Ba,Ca,Mg)₂SiO₄:Eu²⁺, |
| | K₂SiF₆:Mn⁴⁺, SrLiAl₃N₄:Eu, Ln₄₋ₓ(Eu_{z}M_{1-z})ₓSi_{12-y}Al_{y}O_{3+x+y}N_{18-x-y} |
| | (0.5 ≦ x ≦ 3, 0 < z < 0.3, 0 < y ≦ 4), |
| | K₂TiF₆:Mn⁴⁺, NaYF₄:Mn⁴⁺, NaGdF₄:Mn⁴⁺, K₃SiF₇:Mn⁴⁺ |
| Electrical Components | Lu₃Al₅O₁₂:Ce³⁺, Ca-α-SiAlON:Eu²⁺, La₃Si₆N₁₁:Ce³⁺, (Ca, |
| (Head Lamp, etc.) | Sr)AlSiN₃:Eu²⁺, Y₃Al₅O₁₂:Ce³⁺, K₂SiF₆:Mn⁴⁺, |
| | SrLiAl₃N₄:Eu, Ln₄₋ₓ(Eu_{z}M_{1-z})ₓSi_{12-y}Al_{y}O_{3+x+y}N_{18-x-y}(0.5 ≦ x ≦ |
| | 3, 0 < z < 0.3, 0 < y ≦ 4), K₂TiF₆:Mn⁴⁺, NaYF₄:Mn⁴⁺, |
| | NaGdF₄:Mn⁴⁺, K₃SiF₇:Mn⁴⁺ |

In addition, as examples of the wavelength conversion material, quantum dots (QDs) may be used in place of phosphors or may be mixed with phosphors.

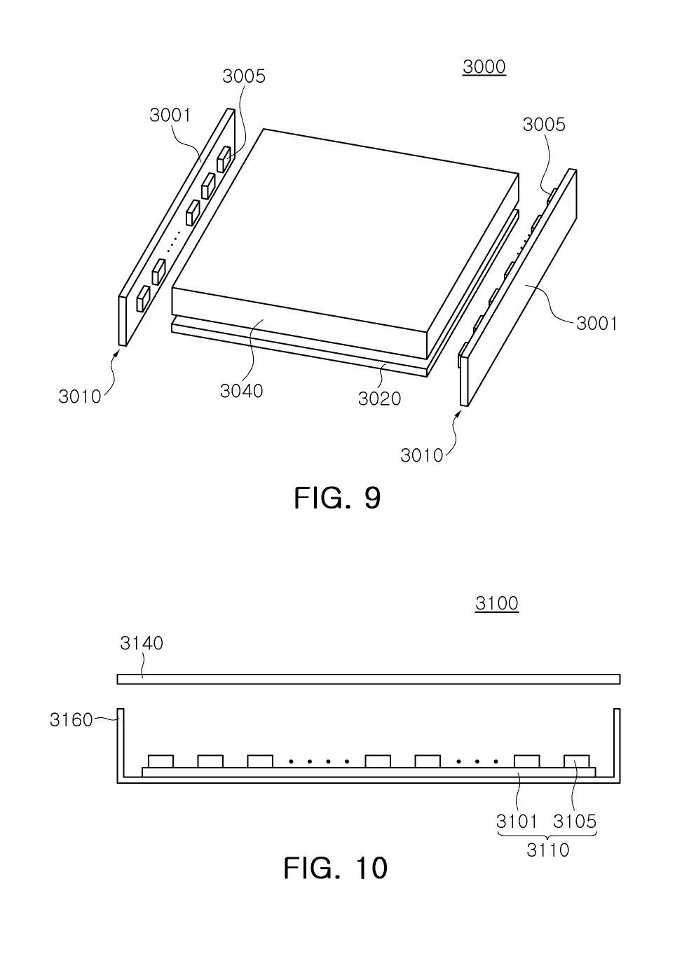

FIG. 9 is a perspective view of a backlight unit including a semiconductor light emitting device according to an example embodiment.

Referring to FIG. 9, a backlight unit 3000 includes a light guide plate 3040 and light source modules 3010 provided on both side surfaces of the light guide plate 3040. In addition, the backlight unit 3000 further includes a reflective plate 3020 disposed below the light guide plate 3040. The backlight unit 3000 in the present example embodiment may be an edge-type backlight unit.

According to example embodiments, the light source modules 3010 may be provided on one side surface of the light guide plate 3040 or three or four side surfaces thereof. The light source module 3010 includes a printed circuit board (PCB) 3001 and a plurality of light emitting devices 3005 mounted on the PCB 3001. Here, the light emitting device 3005 may be the semiconductor light emitting device 100 of FIG. 1, the semiconductor light emitting device 100a of FIG. 5 and/or the semiconductor light emitting device package 1000 of FIG. 6.

FIG. 10 is a cross-sectional view of a backlight unit including a semiconductor light emitting device according to an example embodiment.

Referring to FIG. 10, a backlight unit 3100 includes a light diffusion plate 3140 and light source modules 3110 arrayed below the light diffusion plate 3140. In addition, the backlight unit 3100 further includes a bottom case 3160 disposed below the light diffusion plate 3140 and accommodating the light source modules 3100. The backlight unit 3100 in the present example embodiment may be a direct-type backlight unit.

The light source module 3110 includes a PCB 3101 and a plurality of light emitting devices 3105 mounted on the PCB 3101. Here, the light emitting device 3105 may be the semiconductor light emitting device 100 of FIG. 1, the semiconductor light emitting device 100a of FIG. 5 and/or the semiconductor light emitting device package 1000 of FIG. 6.

FIG. 11 is an exploded perspective view schematically illustrating a lamp including a communication module as an example of a lighting device including a semiconductor light emitting device according to an example embodiment.

Referring to FIG. 11, a lighting device 4000 includes a socket 4010, a power supply 4020, a heat dissipater 4030, a light source module 4040 and a cover 4070. The lighting device 4000 further includes a reflective plate 4050 and a communication module 4060.

Power may be supplied to the lighting device 4000 through the socket 4010. The socket 4010 may have a structure appropriate for use in existing lighting devices. As illustrated, the power supply 4020 may include a first power supply 4021 and a second power supply 4022, which are separately assembled into the lighting device 4000. The heat dissipater 4030 includes an internal heat dissipater 4031 and an external heat dissipater 4032. The internal heat dissipater 4031 may be directly connected to the light source module 4040 and/or the power supply 4020, thereby transferring heat to the external heat dissipater 4032. The cover 4070 may have a structure appropriate for substantially uniform diffusion of light emitted from the light source module 4040.

The light source module 4040 may receive power from the power supply 4020 to emit light to the cover 4070. The light source module 4040 includes one or more light emitting devices 4041, a circuit board 4042 and a controller 4043. The controller 4043 may store driving information of the light emitting devices 4041. Here, the light emitting device 4041 may be the semiconductor light emitting device 100 of FIG. 1, the semiconductor light emitting device 100a of FIG. 5 and/or the semiconductor light emitting device package 1000 of FIG. 6.

The reflective plate 4050 may be disposed above the light source module 4040, and may serve to substantially uniformly diffuse light emitted from the light source module 4040 toward sides and rearwards of the light source module 4040 to thereby reduce glare. The communication module 4060 may be mounted on the reflective plate 4050, and home-network communications may be implemented through the communication module 4060. For example, the communication module 4060 may be a wireless communication module using Zigbee, Wi-Fi, or Li-Fi. The communication module 4060 may control functions of an indoor or outdoor lighting device, such as on/off or brightness control thereof, by using a smartphone or a wireless controller. In addition, the communication module 4060 may control electronics and car systems in and around the home, such as a TV, a refrigerator, an air conditioner, a door-lock, or an automobile, by using a Li-Fi communication module using a wavelength of visible light of the indoor or outdoor lighting device installed in and around the home. The reflective plate 4050 and the communication module 4060 may be covered by the cover 4070.

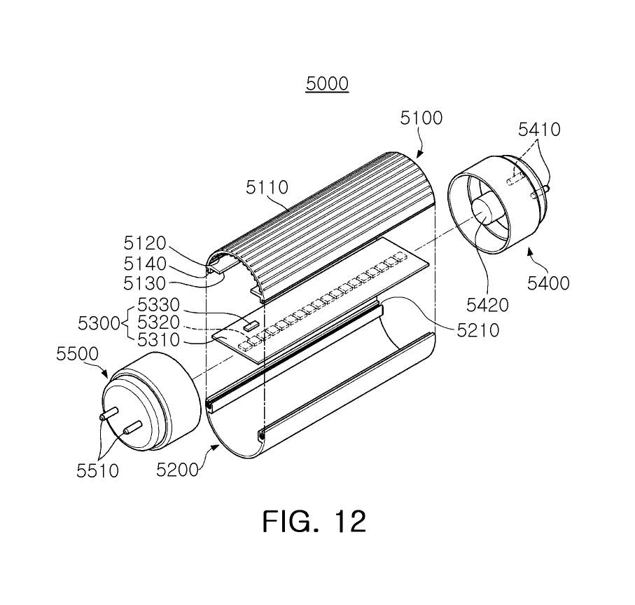

FIG. 12 is an exploded perspective view schematically illustrating a bar-type lamp as an example of a lighting device including a semiconductor light emitting device according to an example embodiment.

Referring to FIG. 12, a lighting device 5000 includes a heat dissipating member 5100, a cover 5200, a light source module 5300, a first socket 5400, and a second socket 5500.

A plurality of heat dissipating fins 5110 and 5120 may be disposed on an inner surface and/or an outer surface of the heat dissipating member 5100 in the form of protrusions and depressions, and the heat dissipating fins 5110 and 5120 may be designed to have a variety of shapes and intervals therebetween. An overhang-type support 5130 may be formed on an inner side of the heat dissipating member 5100. The light source module 5300 may be fastened to the support 5130. A fastening protrusion 5140 may be formed at each edge portion of the heat dissipating member 5100.

A fastening groove 5210 may be formed in the cover 5200, and the fastening protrusion 5140 of the heat dissipating member 5100 may be coupled to the fastening groove 5210 in a hook-coupling structure. Positions of the fastening groove 5210 and the fastening protrusion 5140 may be interchangeable.

The light source module 5300 includes a light emitting device array. The light source module 5300 may include a PCB 5310, a light source 5320, and a controller 5330. The light source 5320 may be the semiconductor light emitting device 100 of FIG. 1, the semiconductor light emitting device 100a of FIG. 5 and/or the semiconductor light emitting device package 1000 of FIG. 6. The controller 5330 may store driving information of the light source 5320. Circuit wirings for operating the light source 5320 may be formed on the PCB 5310. In addition, the PCB 5310 further includes other components mounted thereon to operate the light source 5320.

The pair of first and second sockets 5400 and 5500 may be respectively coupled to both end portions of a cylindrical cover unit that is provided by the heat dissipating member 5100 and the cover 5200. For example, the first socket 5400 includes an electrode terminal 5410 and a power supply 5420, and the second socket 5500 includes a dummy terminal 5510. In addition, an optical sensor and/or a communication module may be embedded in one of the first socket 5400 and the second socket 5500. For example, the optical sensor and/or the communication module may be embedded in the second socket 5500 including the dummy terminal 5510. Alternatively, the optical sensor and/or the communication module may be embedded in the first socket 5400 including the electrode terminal 5410.

According to an example embodiment, an internet of things (IoT) device may be equipped with an accessible wired or wireless interface, and be provided with devices for transmitting or receiving data by communicating with one or more other devices through the wired or wireless interface. The accessible interface includes a modem communication interface accessible to a wired local area network (LAN), a wireless local area network (WLAN) such as a wireless fidelity (Wi-Fi) network, a wireless personal area network (WPAN) such as Bluetooth, a wireless universal serial bus (USB), Zigbee, near field communication (NFC), radio-frequency identification (RFID), power line communication (PLC), or a mobile cellular network, such as a 3rd Generation (3G) network, a 4th Generation (4G) network, or a Long Term Evolution (LTE) network. The Bluetooth interface may support Bluetooth Low Energy (BLE) technology.

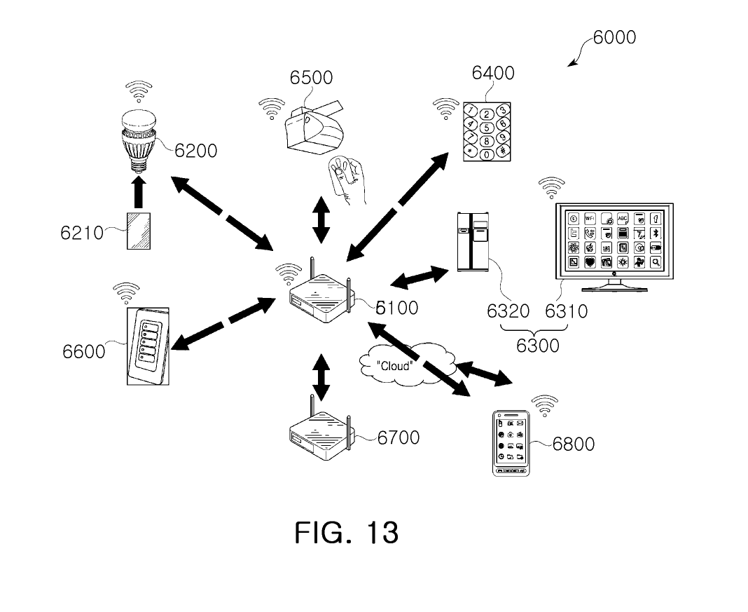

FIG. 13 schematically illustrates an indoor lighting control network system employing a semiconductor light emitting device according to an example embodiment. Here, the light emitting device may be the semiconductor light emitting device 100 of FIG. 1, the semiconductor light emitting device 100a of FIG. 5 and/or the semiconductor light emitting device package 1000 of FIG. 6.

A network system 6000 according to the present example embodiment may be a complex smart lighting-network system in which lighting technology using a light emitting device such as an LED, or the like, is converged with Internet of Things (IoT) technology, wireless communication technology and the like. The network system 6000 may use various lighting devices and wired and/or wireless communication devices, and may be realized by a sensor, a controller, a communication unit, software for network control and maintenance, and the like.

The network system 6000 may be applied even to an open space such as a park or a street, as well as to a closed space within a building such as a house or an office. The network system 6000 may be realized based on the IoT environment to collect and process a variety of information and provide the same to users. Here, an LED lamp 6200 included in the network system 6000 may serve to check and control operational states of other devices 6300 to 6800 included in the IoT environment based on of a function of the LED lamp 6200, such as visible light communications or the like, as well as receiving information regarding a surrounding environment from a gateway 6100 and controlling lighting of the LED lamp 6200.

Referring to FIG. 13, the network system 6000 includes the gateway 6100 processing data transmitted and received according to different communication protocols, the LED lamp 6200 communicatively connected to the gateway 6100 and including an LED light emitting device, and a plurality of devices 6300 to 6800 communicatively connected to the gateway 6100t according to various wireless communication schemes. To realize the network system 6000 based on the IoT environment, each of the devices 6300 to 6800, as well as the LED lamp 6200, includes at least one communication module. In example embodiments, the LED lamp 6200 may be communicatively connected to the gateway 6100 according to wireless communication protocols such as Wi-Fi, ZigBee, or Li-Fi, and to this end, the LED lamp 6200 includes at least one communication module 6210 for a lamp.

As discussed above, the network system 6000 may be applied even to an open space such as a park or a street, as well as to a closed space such as a house or an office. When the network system 6000 is applied to a house, the plurality of devices 6300 to 6800 included in the network system 6000 and communicatively connected to the gateway 6100 based on the IoT technology include a home appliance 6300 such as a television 6310 or a refrigerator 6320, a digital door lock 6400, a garage door lock 6500, a light switch 6600 installed on a wall or the like, a router 6700 for relaying a wireless communication network, and a mobile device 6800 such as a smartphone, a tablet, or a laptop computer.

In the network system 6000, the LED lamp 6200 may check the operational states of various devices 6300 to 6800 using the wireless communication network (ZigBee, Wi-Fi, LI-Fi, or the like) installed in a household or may automatically control illumination of the LED lamp 6200 according to a surrounding environment or situation. Also, the devices 6300 to 6800 included in the network system 6000 may be controlled by using Li-Fi communications using visible light emitted from the LED lamp 6200.

First, the LED lamp 6200 may automatically adjust illumination of the LED lamp 6200 based on information on a surrounding environment transmitted from the gateway 6100 through the communication module 6210 for a lamp or information on a surrounding environment collected from a sensor mounted on the LED lamp 6200. For example, the brightness of the LED lamp 6200 may be automatically adjusted according to types of programs playing on the television 6310 or the brightness of a screen. To this end, the LED lamp 6200 may receive operation information of the TV 6310 from the communication module 6210 for a lamp connected to the gateway 6100. The communication module 6210 for a lamp may be integrally modularized with a sensor and/or a controller included in the LED lamp 6200.

For example, in a case in which a drama is being aired, the network system 6000 may create a cozy atmosphere by controlling a color temperature of light to be decreased to 12,000 K or lower, for example, to 6,000 K, according to preset values, and adjusting a color tone. Conversely, in a case of a comedy program being aired, the network system 6000 may be configured to control a color temperature of light to be increased to 6,000 K or higher, according to preset values, and adjust a color of light to be blue-based white light.

Also, in a case in which no one is at home, when a predetermined time has elapsed after the digital door lock 6400 is locked, all of the turned-on LED lamps 6200 are turned off to prevent a waste of electricity. Also, in a case in which a security mode is set through the mobile device 6800 or the like, when the digital door lock 6400 is locked with no person in home, the LED lamp 6200 may be maintained in a turned-on state.

An operation of the LED lamp 6200 may be controlled according to information on surrounding environments collected through various sensors connected to the network system 6000. For example, in a case in which the network system 6000 is provided in a building, lighting, a position sensor, and a communication module are connected to each other within the building, such that lighting is turned on or turned off based on position information of a user in the building, or the position information may be provided in real time to effectively manage facilities or effectively utilize underused space. In general, a lighting device such as the LED lamp 6200 is disposed in almost every space of each floor of a building, and thus, various types of information of the building may be collected through a sensor integrally provided with the LED lamp 6200 and used for managing facilities and utilizing underused space.

The LED lamp 6200 may be combined with an image sensor, a storage device, and the communication module 6210 for a lamp, to be utilized for maintaining building security or sensing and coping with an emergency situation. For example, in a case in which a smoke or temperature sensor, or the like, is attached to the LED lamp 6200, the outbreak of fire may be promptly detected to minimize damage. Also, brightness of lighting may be adjusted in consideration of outside weather conditions and/or an amount of sunshine, thereby saving energy and providing a satisfactory illumination environment.

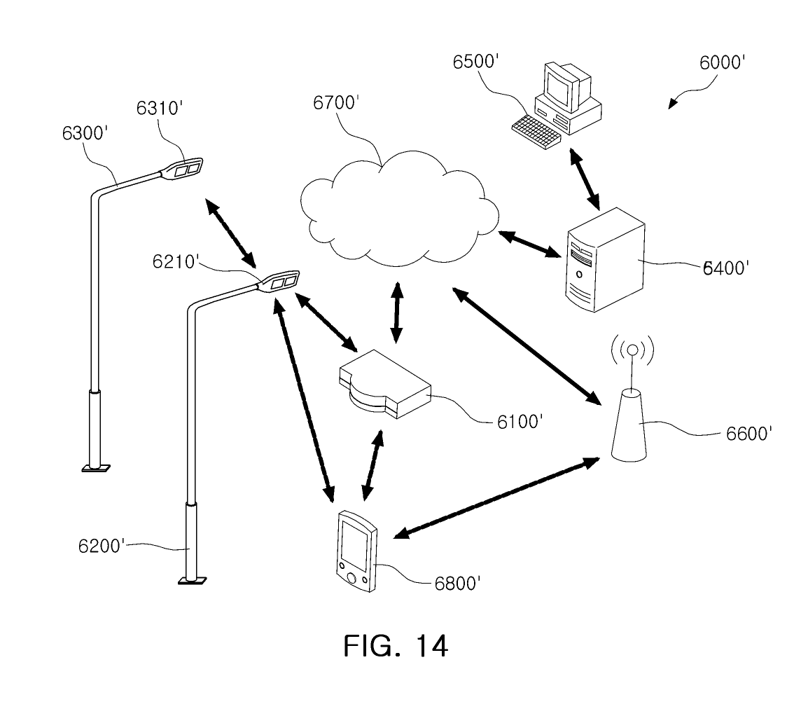

FIG. 14 schematically illustrates an example of an open-type network system employing a semiconductor light emitting device according to an example embodiment. Here, the light emitting device may be the semiconductor light emitting device 100 of FIG. 1, the semiconductor light emitting device 100a of FIG. 5 and/or the semiconductor light emitting device package 1000 of FIG. 6.

Referring to FIG. 14, a network system 6000′ according to the present example embodiment includes a communication connection device 6100′, a plurality of lighting fixtures 6200′ and 6300′ installed at a predetermined interval and communicatively connected to the communication connection device 6100′, a server 6400′, a computer 6500′ for managing the server 6400′, a communication base station 6600′, a communication network 6700′ for establishing a communication link between the aforementioned devices, a mobile device 6800′ and the like.

The plurality of lighting fixtures 6200′ and 6300′ installed in an open outdoor space such as a street or a park includes smart engines 6210′ and 6310′, respectively. Each of the smart engines 6210′ and 6310′ includes a light emitting device emitting light, a driver for driving the light emitting device, a sensor collecting information of a surrounding environment, a communication module, and the like. The smart engines 6210′ and 6310′ may communicate with other neighboring equipment through the communication module according to communication protocols such as Wi-Fi, ZigBee, and Li-Fi.

For example, a single smart engine 6210′ may be communicatively connected to another smart engine 6310′. Here, a Wi-Fi extending technique (e.g., Wi-Fi mesh) may be applied to communications between the smart engines 6210′ and 6310′. At least one smart engine 6210′ may be connected to the communication connection device 6100′ connected to the communication network 6700′ through wired/wireless communications. To improve communication efficiency, some smart engines 6210′ and 6310′ may be grouped and connected to a single communication connection device 6100′.

The communication connection device 6100′ may be an access point (AP) available for wired and/or wireless communications, which may relay communications between the communication network 6700′ and other equipment. The communication connection device 6100′ may be connected to the communication network 6700′ in a wired manner and/or a wireless manner, and for example, the communication connection device 6100′ may be mechanically received in any one of the lighting fixtures 6200′ and 6300′.

The communication connection device 6100′ may be connected to the mobile device 6800′ through a communication protocol such as Wi-Fi, or the like. A user of the mobile device 6800′ may receive surrounding environment information collected by the plurality of smart engines 6210′ and 6310′ through the communication connection device 6100′ connected to the smart engine 6210′ of the lighting fixture 6200′ adjacent to the mobile device 6800′. The surrounding environment information includes nearby traffic information, weather information, and the like. The mobile device 6800′ may be connected to the communication network 6700′ according to a wireless cellular communication scheme such as 3G or 4G through the communication base station 6600′.

The server 6400′ connected to the communication network 6700′ may receive information collected by the smart engines 6210′ and 6310′ respectively installed in the lighting fixtures 6200′ and 6300′ and may monitor an operational state, or the like, of each of the lighting fixtures 6200′ and 6300′. To manage the lighting fixtures 6200′ and 6300′ based on the monitoring results of the operational states of the lighting fixtures 6200′ and 6300′, the server 6400′ may be connected to the computer 6500′ providing a management system. The computer 6500′ may execute software, or the like, capable of monitoring and managing the operational states of the lighting fixtures 6200′ and 6300′, particularly, the smart engines 6210′ and 6310′.

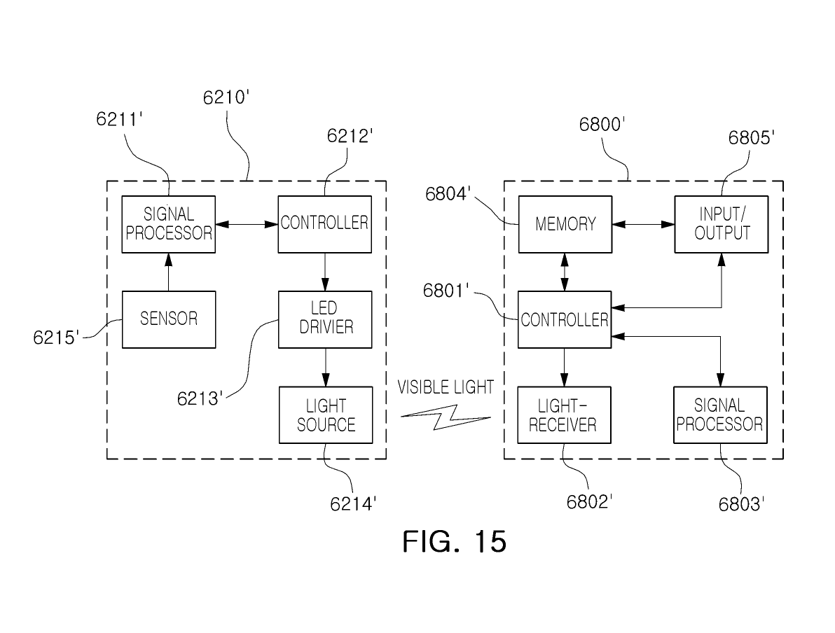

FIG. 15 is a block diagram illustrating communications between a mobile device and a smart engine of a lighting fixture employing a semiconductor light emitting device according to an example embodiment through visible light communications. Here, the light emitting device may be the semiconductor light emitting device 100 of FIG. 1, the semiconductor light emitting device 100a of FIG. 5 and/or the semiconductor light emitting device package 1000 of FIG. 6.

Referring to FIG. 15, a smart engine 6210′ includes a signal processor 6211′, a controller 6212′, an LED driver 6213′, a light source 6214′, and a sensor 6215′. The mobile device 6800′ includes a controller 6801′, a light receiver 6802′, a signal processor 6803′, a memory 6804′, and an input/output port 6805′.

Visible light communication (Li-Fi) technology is a wireless communication technology for transmitting information wirelessly using visible light having a wavelength band that may be perceived by the human eye. Such visible light communications differ from existing wired optical communications and infrared wireless communications with respect to the use of visible light, that is, a specific frequency of visible light from the light emitting device according to the example embodiment, and differ from wired optical communications with respect to the use of a wireless communication environment. In addition, unlike RF wireless communications, visible light communications are convenient in that the visible light communications may use a frequency without regulation or permission, have excellent physical security, and a user is able to see communications links with his or her eyes. Moreover, visible light communications are characterized by convergence technology which achieves an original purpose as a light source and a communication function at the same time.

The signal processor 6211′ of the smart engine 6210′ may process data to be transmitted and/or received using visible light communications. In example embodiments, the signal processor 6211′ may process information collected by the sensor 6215′ into data and transmit the data to the controller 6212′. The controller 6212′ may control the operations of the signal processor 6211′ and the LED driver 6213′ and, in particular, the operations of the LED driver 6213′ based on the data transmitted by the signal processor 6211′. The LED driver 6213′ may allow the light source 6214′ to emit light according to a control signal transmitted by the controller 6212′, and transmit data to the mobile device 6800′.

The mobile device 6800′ may include the controller 6801′, the memory 6804′ for storing data, the input/output port 6805′ including a display, a touch screen and an audio output port, the signal processor 6803′, and the light receiver 6802′ for recognizing visible light including data. The light receiver 6802′ may detect visible light and convert the detected visible light into an electric signal, and the signal processor 6803′ may decode data included in the electric signal converted by the light receiver 6802′. The controller 6801′ may store the data decoded by the signal processor 6803′ in the memory 6804′, or output the data through the input/output port 6805′ so that a user is able to recognize the data.

As set forth above, according to example embodiments, a semiconductor light emitting device is provided with a reflector including a low refractive index layer, thereby achieving improved light extraction efficiency.

While example embodiments have been shown and described above, it will be apparent to those skilled in the art that modifications and variations could be made without departing from the scope of the invention as defined by the appended claims.

What is claimed is:

1. A semiconductor light emitting device, comprising:
a substrate having a first surface and a second surface, the second surface being opposite to the first surface;
a light emitting structure disposed on the first surface of the substrate and comprising a first conductivity-type semiconductor layer, an active layer and a second conductivity-type semiconductor layer; and
a reflector disposed on the second surface of the substrate and comprising a low refractive index layer and a Bragg layer,
wherein the Bragg layer comprises a plurality of alternately stacked layers having different refractive indices, and
wherein a refractive index of the low refractive index layer is lower than a refractive index of the Bragg layer.

2. The semiconductor light emitting device of claim 1, wherein the low refractive index layer comprises a plurality of layers.

3. The semiconductor light emitting device of claim 1, wherein the low refractive index layer comprises a first refractive index layer and a second refractive index layer, and
the first and second refractive index layers are disposed on first and second surfaces of the Bragg layer, respectively.

4. The semiconductor light emitting device of claim 3, wherein the first low refractive index layer, the Bragg layer, and the second low refractive index layer are sequentially stacked on the substrate.

5. The semiconductor light emitting device of claim 3, wherein the first and second refractive index layers have different thicknesses.

6. The semiconductor light emitting device of claim 3, wherein the first and second refractive index layers have the same refractive index or different refractive indices.

7. The semiconductor light emitting device of claim 3, wherein light reflected by the first refractive index layer has a wavelength different from a wavelength of light reflected by the second refractive index layer.

8. The semiconductor light emitting device of claim 1, wherein the low refractive index layer has a refractive index (n), which is in a range of 1≦n<1.4.

9. The semiconductor light emitting device of claim 1, wherein the low refractive index layer has a thickness of 0.8λ/n or greater,
where λ denotes a wavelength of light generated by the active layer and n denotes a refractive index of the low refractive index layer.

10. The semiconductor light emitting device of claim 1, wherein the low refractive index layer comprises at least one selected from the group consisting of porous SiO₂, porous SiO and MgF₂.

11. The semiconductor light emitting device of claim 1, wherein the low refractive index layer is disposed on a surface of the Bragg layer.

12. The semiconductor light emitting device of claim 1, wherein the Bragg layer comprises first layers having a first refractive index and second layers having a second refractive index higher than the first refractive index, and
the refractive index of the low refractive index layer is lower than the first refractive index of the first layers.

13. The semiconductor light emitting device of claim 1, wherein at least one of the low refractive index layer and the Bragg layer comprises a dielectric material.

14. A semiconductor light emitting device, comprising:
a light emitting structure comprising a first conductivity-type semiconductor layer, an active layer and a second conductivity-type semiconductor layer;
a Bragg layer disposed on a surface of the light emitting structure and comprising a plurality of alternately stacked layers having different refractive indices; and
a low refractive index layer disposed on at least one surface of the Bragg layer and having a refractive index lower than a refractive index of the Bragg layer.

15. The semiconductor light emitting device of claim 14, wherein the Bragg layer comprises first layers having a first refractive index and second layers having a second refractive index higher than the first refractive index, and
the low refractive index layer has a thickness greater than a thickness of each of the first and second layers.

16. A semiconductor light emitting diode (LED) chip comprising a first surface, on which a first electrode and a second electrode are disposed, and a second surface being opposite to the first surface, the semiconductor LED chip further comprising:
a reflector disposed on the second surface of the semiconductor LED chip, wherein the reflector comprises a low refractive index layer and a Bragg layer, a refractive index of the low refractive index layer being lower than a refractive index of the Bragg layer.

17. The semiconductor LED chip of claim 16, wherein the low refractive index layer has a refractive index (n), which is in a range of 1≦n<1.4.

18. The semiconductor LED chip of claim 16, wherein the low refractive index layer has a thickness equal to or greater than about 300 nm.

19. The semiconductor LED chip of claim 16, wherein the low refractive index layer is provided to at least one surface of the Bragg layer.

20. The semiconductor LED Chip of claim 16, wherein the low refractive index layer comprises a plurality of refractive index layers having the same refractive index or different refractive indices.
